(19) United States
(12) Patent Application Publication
(10) Pub. No.: US 2015/0200306 A1
(43) Pub. Date: Jul. 16, 2015

(54) Non-Volatile Memory And Manufacturing Method Of Same

(71) Applicant: Macronix International Co., Ltd., Hsinchu (TW)

(72) Inventors: Guan-Wei Wu, Renwu Township (TW); Yao-Wen Chang, Hsinchu City (TW); I-Chen Yang, Changhua City (TW); Tao-Cheng Lu, Hsinchu City (TW)

(73) Assignee: Macronix International Co., Ltd., Hsinchu (TW)

(21) Appl. No.: 14/154,991

(22) Filed: Jan. 14, 2014

(51) Int. Cl. H01L 29/792; H01L 21/266; H01L 21/28; H01L 29/51; H01L 29/66

(52) U.S. Cl. CPC H01L 29/792; H01L 29/513; H01L 29/517; H01L 29/66833; H01L 21/28282; H01L 21/266; H01L 29/518

(57) ABSTRACT

A non-volatile memory includes a substrate, a charge trapping structure disposed on the substrate, a buffer layer disposed on the charge trapping structure, and a plurality of conductive layers disposed on the buffer layer.

### FIELD OF THE DISCLOSURE

The present disclosure relates to a non-volatile memory and a manufacturing method of same and, more particularly, to a non-volatile memory having a buffer layer and a method for manufacturing the memory.

### BACKGROUND OF THE DISCLOSURE

A non-volatile memory is a semiconductor memory which is able to continuously store data in a plurality of memory cells even when its power supply is turned off. A charge trapping flash memory is a common type of non-volatile memory. In the charge trapping flash memory, multi-bit data can be programmed and stored in a memory cell having a charge trapping structure of an oxide-nitride-oxide layer (i.e., an ONO layer) by setting a certain amount of charge in the memory cell. The amount of charge in the memory cell is then measured by a sensing circuit, to read the multi-bit data stored in the cell,

However, due to charge loss from the charge trapping structure over time, the measurement of the amount of charge may experience errors. As the size of the charge trapping flash memory is scaled down, the effect of charge loss worsens, thereby negatively affecting the operation window and performance of the memory.

### SUMMARY

According to an embodiment of the disclosure, a non-volatile memory is provided. The non-volatile memory includes a substrate, a charge trapping structure disposed on the substrate, a buffer layer disposed on the charge trapping structure, and a plurality of conductive layers disposed on the buffer layer.

According to another embodiment of the disclosure, a method of manufacturing a non-volatile memory is provided. The method includes forming a charge trapping structure on a substrate, forming a buffer layer on the charge trapping structure, forming a conductive layer on the buffer layer, and patterning the conductive layer.

### BRIEF DESCRIPTION OF THE DRAWINGS

FIG. 1A schematically illustrates a top view of a non-volatile memory according to an embodiment.

FIG. 1B schematically illustrates a cross-sectional view of a memory cell in the non-volatile memory taken along line B-B′ of FIG. 1A.

FIG. 1C schematically illustrates a partial cross-sectional view of the non-volatile memory of FIG. 1A taken along line C-C′ of FIG. 1A.

FIGS. 2A to 2F schematically illustrate partial cross-sectional views of the non-volatile memory taken along line B-B′ of FIG. 1A, during steps of a process for manufacturing the non-volatile memory.

FIGS. 3A to 3F schematically illustrate partial cross-sectional views of the non-volatile memory taken along line C-C′ of FIG. 1A, during steps of a process for manufacturing the non-volatile memory.

### DESCRIPTION

Reference will now be made in detail to the present embodiments, examples of which are illustrated in the accompanying drawings. Wherever possible, the same reference numbers will be used throughout the drawings to refer to the same or like parts.

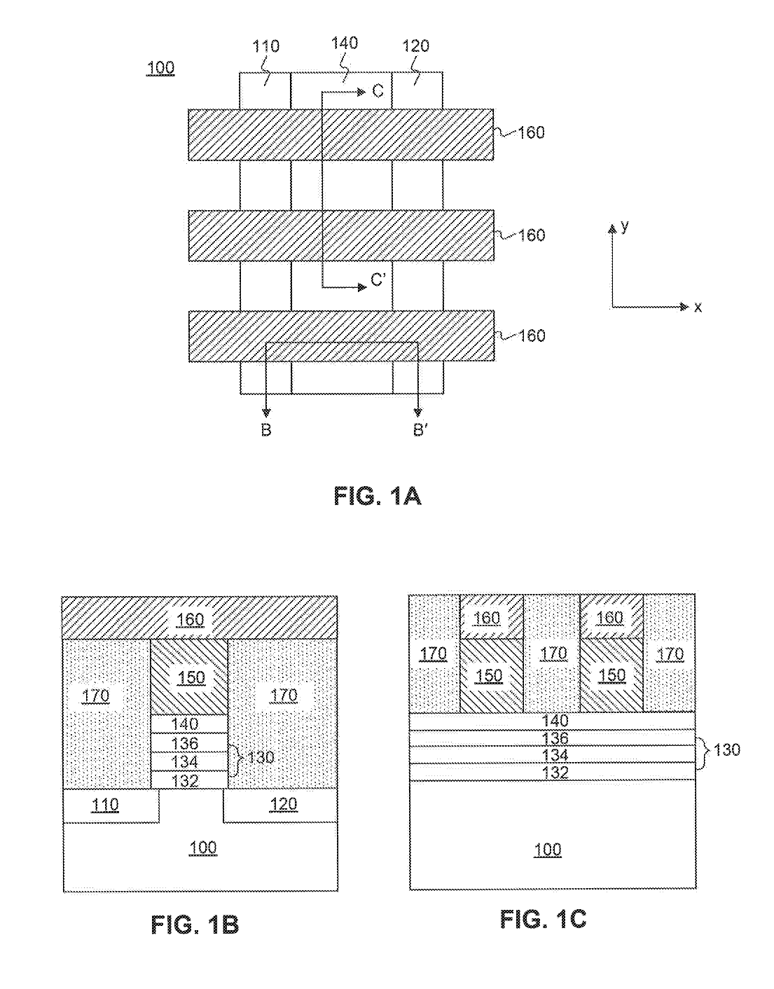

FIG. 1A schematically illustrates a top view of a non-volatile memory according to an embodiment. FIG. 1B schematically illustrates a partial cross-sectional view of the non-volatile memory of FIG. 1A taken along line B-B′ of FIG. 1A. FIG. 1C schematically illustrates a partial cross-sectional view of the non-volatile memory of FIG. 1A taken along line C-C′ of FIG. 1A.

Referring to FIGS. 1A-1C, the non-volatile memory according to the embodiment includes a substrate 100, a first doped region 110 having a stripe shape and extending along a Y-direction, a second doped region 120 having a stripe shape and extending along the Y-direction, a charge trapping structure 130 disposed on substrate 100 between first doped region 110 and second doped region 120, a buffer layer 140 disposed on charge trapping structure 130 and covering charge trapping structure 130, a plurality of first conductive layers 150 disposed on buffer layer 140, a plurality of second conductive layers 160 disposed on first conductive layers 150, each second conductive layer 160 having a stripe shape and extending along an X-direction, an insulating layer 170 formed on substrate 100, covering sidewalls of charge trapping structure 130, buffer layer 140, first conductive layers 150, and second conductive layers 160. Charge trapping structure 130 is a composite structure including a bottom oxide layer 132, a charge trapping layer 134, and a top oxide layer 136. Charge trapping layer 134 is made of an electrically insulating material, or a material having low electrical conductivity. Suitable materials for charge trapping layer 134 include nitride or a dielectric material, such as HfO₂, TiO₂, ZrO₂, Ta₂O₅, and Al₂O₃. The thickness of bottom oxide layer 132 is about 40 Å to 50 Å. The thickness of charge trapping layer 134 is about 60 Å to 100 Å. The thickness of top oxide layer 136 is about 70 Å to 110 Å. Both of first conductive layers 150 and second conductive layers 160 are made of an electrically conductive material such as, for example, polysilicon. Second conductive layers 160 function as word lines for applying voltage across charge trapping structure 130. First conductive layers 150 function to conduct voltage between second conductive layers 160 and charge trapping structure 130.

Buffer layer 140 covers charge trapping structure 130 to protect top oxide layer 136 from being damaged during an etching process for forming first conductive layers 150. Buffer layer 140 is formed of a material having an etching rate lower than that of first conductive layers 150, Suitable materials for buffer layer 140 include a nitride material such as Si₃N₄ and silicon-rich nitride, and a high-k material such as HfO₂, TiO₂, ZrO₂, Ta₂O₅, or Al₂O₃. The thickness of buffer layer 140 is about 10 Å to about 20 Å.

A memory cell in the non-volatile memory can be programmed to trap charge (i.e., electrons) in charge trapping layer 134. The electrons trapped in charge trapping layer 134 increase a threshold voltage of the memory cell. Consequently, the memory cell is programmed from logic “1” to logic “0”.

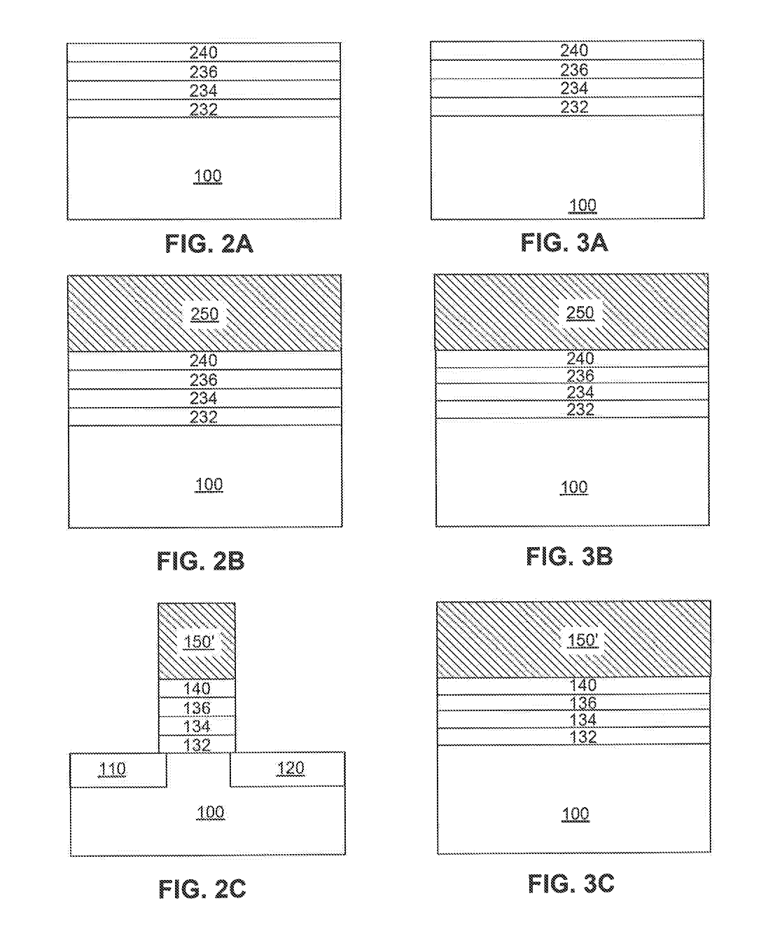

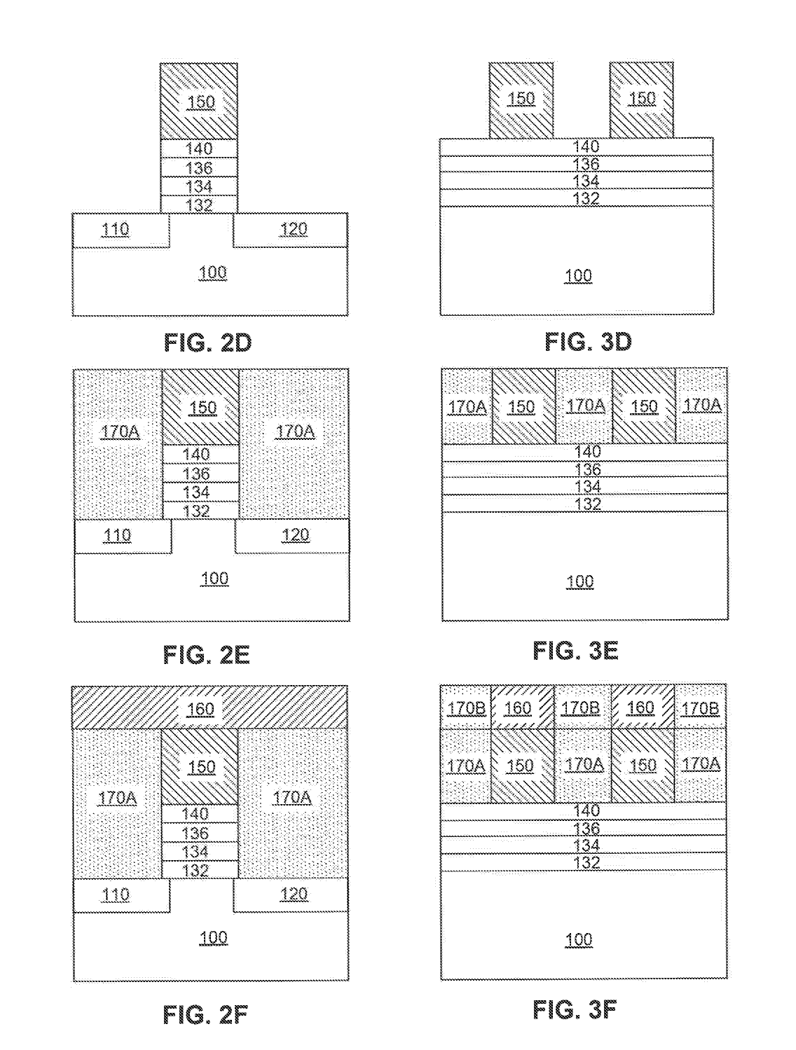

FIGS. 2A to 2F schematically illustrate partial cross-sectional views of the non-volatile memory taken along line B-B′ of FIG. 1A, during steps of a process for manufacturing the non-volatile memory. FIGS. 3A to 3F schematically illustrate partial cross-sectional views of the non-volatile memory taken along line C-C′ of FIG. 1A, during steps of the process for manufacturing the non-volatile memory illustrated in FIGS. 2A-2F.

First, referring to FIGS. 2A and 3A, substrate 100 is provided. Thereafter, a bottom oxide layer 232, a charge trapping layer 234, a top oxide layer 236, and a buffer layer 240 are sequentially formed on substrate 100. More particularly, bottom oxide layer 232 is formed on substrate 100, charge trapping layer 234 is formed on bottom oxide layer 232, top oxide layer 236 is formed on charge trapping layer 234, and buffer layer 240 is formed on top oxide layer 236.

Next, referring to FIGS. 2B and 3B, a conductive layer 250 is formed on the entire surface of buffer layer 240. Conductive layer 250 is formed of, for example, polysilicon.

Referring to FIGS. 2C and 3C, bottom oxide layer 232, charge trapping layer 234, top oxide layer 236, buffer layer 240, and conductive layer 250 are patterned to form bottom oxide layer 132, charge trapping layer 134, top oxide layer 136, buffer layer 140, and a patterned conductive layer 150′ each having a stripe shape extending along the Y direction as illustrated in FIG. 1A. The method of patterning layers 232, 234, 236, 240, and 250 includes photolithography followed by an etching process. Then, substrate 100 is selectively doped by using the structure including bottom oxide layer 132, charge trapping layer 134, top oxide layer 136, buffer layer 140, and conductive layer 150′ as a mask, to form first doped region 110 and second doped region 120.

Referring to FIGS. 2D and 3D, patterned conductive layer 150′ is patterned to form the plurality of first conductive layers 150. The method of patterning patterned conductive layer 150′ includes photolithography followed by an etching process. Buffer layer 140 is provided to protect top oxide layer 136 from direct exposure to an exterior environment during the etching process of patterned conductive layer 150′. If not so protected, top oxide layer 136 could be partially etched. Such damage to top oxide layer 136 due to etching could result in defect sites being generated at the damaged portion. Such defect sites could provide a charge loss path through which trapped charges can escape from charge trapping layer 134 to first conductive layer 150 and second conductive layer 160. The loss of charge via the charge loss path could result in a change in the threshold voltage of the memory cell, and programmed data could be lost.

In the embodiment of the present disclosure, because top oxide layer 136 is covered by buffer layer 140, top oxide layer 136 is not directly exposed to an exterior environment. Therefore, top oxide layer 136 is not etched during the etching process of patterned conductive layer 150′. As a result, top oxide layer 136 is not damaged, and charge loss through a damaged top oxide layer is prevented.

Referring to FIGS. 2E and 3E, a first insulating layer 170a is formed on substrate 100, covering sidewalls of bottom oxide layer 132, charge trapping layer 134, top oxide layer 136, buffer layer 140, and first conductive layers 150. First insulating layer 170a can be comprised of silicon oxide, and can be formed by oxidation.

Referring to FIG. 2F and 3F, the plurality of second conductive layers 160 are formed on first conductive layers 150, and first insulating layer 170a. As illustrated in FIG. 1A, each of second conductive layers 160 is formed in a stripe shape extending along the X direction. The method of forming second conductive layers 160 is similar to the method of forming first conductive layers 150. Next, a second insulating layer 170b is formed on first insulating layer 170a, covering sidewalls of second conductive layer 160. Second insulating layer 170b can be comprised of the same material as that of first insulating layer 170a, thus forming insulating layer 170 as illustrated in FIGS. 1B and 1C. Alternatively, second insulating layer 170b can be comprised of a material different from that of first insulating layer 170a.

While the embodiment described above is directed to the non-volatile memory shown in FIGS. 1A-1C and fabrication methods thereof shown in FIGS. 2A-2F and 3A-3F, those skilled in the art will now appreciate that the disclosed concepts are equally applicable to other charge trapping non-volatile memory.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A non-volatile memory, comprising:
a substrate;
a charge trapping structure disposed on the substrate;
a buffer layer disposed on the charge trapping structure; and
a plurality of conductive layers directly disposed on the buffer layer.

2. The non-volatile memory of claim 1, wherein the buffer layer is made of a nitride material selected from a group of Si₃N₄ and silicon-rich nitride.

3. The non-volatile memory of claim 1, wherein the buffer layer is made of a high-k material selected from a group of HfO₂, TiO₂, ZrO₂, Ta₂O₅, or Al₂O₃.

4. The non-volatile memory of claim 1, wherein the buffer layer is made of a material having an etching rate lower than that of the conductive layers.

5. The non-volatile memory of claim 1, wherein a thickness of the buffer layer is about 10 Å to about 20 Å.

6. The non-volatile memory of claim 1, wherein the charge trapping structure includes a bottom oxide layer, a charge trapping layer on the bottom oxide layer, and a top oxide layer on the charge trapping layer.

7. The non-volatile memory of claim 6, wherein the charge trapping layer is made of a nitride material or a high-k material.

8. The non-volatile memory of claim 1, further including:
a first doped region having a stripe shape and extending along a first direction orthogonal to a second direction along which the plurality of conductive layers extend; and
a second doped region having a stripe shape and extending along the first direction,
wherein the charge trapping structure is disposed in a region between the first doped region and the second doped region.

9. A method of manufacturing a non-volatile memory, comprising;
forming a charge trapping structure on a substrate;
forming a buffer layer on the charge trapping structure;
forming a conductive layer on the buffer layer; and
patterning the conductive layer.

10. The method of claim 9, wherein forming the buffer layer includes forming a layer of a nitride material selected from a group of Si₃N₄ and silicon-rich nitride.

11. The method of claim 9, wherein forming the buffer layer includes forming a layer of a high-k material selected from a group of HfO₂, TiO₂, ZrO₂, Ta₂O₅, or Al₂O₃.

12. The method of claim 9, wherein forming the buffer layer includes forming a layer of a material having an etching rate lower than that of the conductive layer.

13. The method of claim 9, wherein the buffer layer is formed to have a thickness of about 10 Å to about 20 Å.

14. The method of claim 9, wherein forming the charge trapping structure includes forming a bottom oxide layer, forming a charge trapping layer on the bottom oxide layer, and forming a top oxide layer on the charge trapping layer.

15. The method of dam 14, wherein forming the charge trapping layer includes forming a layer of a nitride material or a high-k material.

16. The method of claim 9, further including selectively doping the substrate by using the charge trapping structure and the patterned conductive layer as a mask structure to form a first doped region and a second doped region.
